(19) United States
(12) Patent Application Publication
(10) Pub. No.: US 2025/0140671 A1
(43) Pub. Date: May 1, 2025

(54) ELECTRONIC DEVICE AND MANUFACTURING METHOD THEREOF

(71) Applicant: Innolux Corporation, Miaoli County (TW)

(72) Inventors: Cheng-Chi Wang, Miaoli County (TW); Wen-Hsiang Liao, Miaoli County (TW); Jui-Jen Yueh, Miaoli County (TW); Ju-Li Wang, Miaoli County (TW)

(73) Assignee: Innolux Corporation, Miaoli County (TW)

(21) Appl. No.: 18/896,935

(22) Filed: Sep. 26, 2024

Related U.S. Application Data
(60) Provisional application No. 63/594,039, filed on Oct. 30, 2023.

(30) Foreign Application Priority Data
Jul. 15, 2024 (CN) 202410945523.7

(51) Int. Cl. H01L 23/498; H01L 21/48; H01L 23/00; H01L 23/31; H01L 23/367

(52) U.S. Cl. CPC H01L 23/49833; H01L 21/4853; H01L 23/3675; H01L 23/49816; H01L 23/3107; H01L 23/49894; H01L 24/13; H01L 24/16; H01L 24/32; H01L 24/33; H01L 24/73; H01L 2224/13105; H01L 2224/13144; H01L 2224/13147; H01L 2224/13155; H01L 2224/16227; H01L 2224/16502; H01L 2224/32225; H01L 2224/33181; H01L 2224/73204

(57) ABSTRACT

An electronic device includes an electronic unit and a circuit structure. The circuit structure is electrically connected to the electronic unit and includes a first circuit structure, a second circuit structure, a bonding pad, and an adjustment layer. The first circuit structure includes at least one first circuit layer and at least one first insulation layer. The second circuit structure is disposed between the electronic unit and the first circuit structure, and includes at least one second circuit layer and at least one second insulation layer. The bonding pad and the adjustment layer are disposed between the second circuit structure and the first circuit structure. A coefficient of thermal expansion of the adjustment layer is smaller than that of at least one of the at least one first insulation layer of the first circuit structure and the at least one second insulation layer of the second circuit structure.

### CROSS-REFERENCE TO RELATED APPLICATION

This application claims the priority benefits of U.S. provisional application Ser. No. 63/594,039, filed on Oct. 30, 2023, and China application serial no. 202410945523.7, filed on Jul. 15, 2024. The entirety of each of the above-mentioned patent applications is hereby incorporated by reference herein and made a part of this specification.

### BACKGROUND

### Technical Field

The present disclosure relates to an electronic device and a manufacturing method thereof, and particularly relates to an electronic device with improved structural reliability and a manufacturing method thereof.

### Description of Related Art

To develop packaging for higher performance and more complex semiconductor chips, the number of layers in the redistribution layer (RDL) continues to increase. However, with the increase in the number of layers of the redistribution layer, it also causes severe warpage problems on the substrate during production, which affects the process accuracy of the pads corresponding to the chip on the topmost layer, and also affects the yield of the subsequent chip bonding the reliability of subsequent products.

### SUMMARY

The present disclosure is directed to an electronic device, which has better structural reliability.

The present disclosure is directed to a manufacturing method of an electronic device, used to produce the aforementioned electronic device.

According to an embodiment of the present disclosure, the electronic device includes an electronic unit and a circuit structure. The circuit structure is electrically connected to the electronic unit, and the circuit structure includes a first circuit structure, a second circuit structure, a bonding pad, and an adjustment layer. The first circuit structure includes at least one first circuit layer and at least one first insulation layer surrounding the at least one first circuit layer. The second circuit structure is disposed between the electronic unit and the first circuit structure. The second circuit structure includes at least one second circuit layer and at least one second insulation layer surrounding the at least one second circuit layer. The bonding pad is disposed between the second circuit structure and the first circuit structure. The adjustment layer is disposed between the second circuit structure and the first circuit structure and surrounds the bonding pad. A coefficient of thermal expansion of the adjustment layer is smaller than a coefficient of thermal expansion of at least one of the at least one first insulation layer of the first circuit structure and the at least one second insulation layer of the second circuit structure.

According to an embodiment of the present disclosure, the electronic device includes an electronic unit and a circuit structure. The circuit structure is electrically connected to the electronic unit, and the circuit structure includes a first circuit structure, a second circuit structure, a bonding pad, and an adjustment layer. The first circuit structure includes at least one first circuit layer and at least one first insulation layer surrounding the at least one first circuit layer. The second circuit structure is disposed between the electronic unit and the first circuit structure. The second circuit structure includes at least one second circuit layer and at least one second insulation layer surrounding the at least one second circuit layer. The bonding pad is disposed between the second circuit structure and the first circuit structure. The adjustment layer is disposed between the second circuit structure and the first circuit structure and surrounds the bonding pad. A thermal expansion trend of the adjustment layer is different from a thermal expansion trend of at least one of the at least one first insulation layer of the first circuit structure and the at least one second insulation layer of the second circuit structure.

According to an embodiment of the present disclosure, a method of manufacturing an electronic device includes the following steps. A first circuit structure and a second circuit structure are provided. The first circuit structure includes at least one first circuit layer, at least one first insulation layer surrounding the at least one first circuit layer, and at least one first groove penetrating through the at least one first insulation layer. The second circuit structure includes at least one second circuit layer, at least one second insulation layer surrounding the at least one second circuit layer, and at least one second groove penetrating through the at least one second insulation layer. The at least one first groove corresponds to the at least one second groove. A bonding pad and an adjustment layer between the first circuit structure and the second circuit structure are provided. A thermal expansion coefficient of the adjustment layer is smaller than a thermal expansion coefficient of at least one of the at least one first insulation layer of the first circuit structure and the at least one second insulation layer of the second circuit structure. The first circuit structure and the second circuit structure are bonded through the bonding pad. The adjustment layer surrounds the bonding pad and fills the at least one first groove and the at least one second groove. At least one electronic unit is disposed on the second circuit structure. A singulation process is performed along the at least one first groove and the at least one second groove to form at least one electronic device. The first circuit structure, the second circuit structure, the bonding pad, and the adjustment layer are defined as a circuit structure, and the at least one electronic unit is electrically connected to the circuit structure.

Based on the above, in an embodiment of the present disclosure, the adjustment layer is disposed between the second circuit structure and the first circuit structure and surrounds the bonding pad, wherein the thermal expansion coefficient of the adjustment layer is smaller than the thermal expansion coefficient of at least one of the first insulation layer of the first circuit structure and the second insulation layer of the second circuit structure, thereby effectively reducing the warping of the substrate, ensuring the process accuracy of the bonding pads corresponding to the electronic unit located in the topmost layer, and enabling the electronic device of the present disclosure to have better structural reliability.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A is a cross-sectional view of an electronic device according to an embodiment of the present disclosure.

FIG. 1B is a top view of the second circuit structure of FIG. 1A.

FIG. 2 is a cross-sectional view of an electronic device according to another embodiment of the present disclosure.

FIG. 3 is a cross-sectional view of an electronic device according to another embodiment of the present disclosure.

FIG. 4 is a cross-sectional view of an electronic device according to another embodiment of the present disclosure.

FIG. 5A to FIG. 5E are cross-sectional views illustrating a method of manufacturing an electronic device according to an embodiment of the present disclosure.

FIG. 6A to FIG. 6C are cross-sectional views illustrating partial steps of a method of manufacturing an electronic device according to another embodiment of the present disclosure.

FIG. 7 is a cross-sectional view illustrating a partial step of a method of manufacturing an electronic device according to another embodiment of the present disclosure.

### DESCRIPTION OF THE EMBODIMENTS

Reference will now be made in detail to exemplary embodiments of the disclosure, examples of which are illustrated in the accompanying drawings. Wherever possible, the same reference numerals are used in the drawings and description to refer to the same or like parts.

The disclosure may be understood with reference to the following detailed description together with the accompanying drawings. It should be noted that, for ease of understanding by readers and conciseness of the drawings, a plurality of drawings in the disclosure merely shows a part of an electronic device, and specific elements in the drawings are not drawn to scale. In addition, the number and size of the elements in the drawings only serve for exemplifying instead of limiting the scope of the disclosure.

Certain terms are used throughout the description and the appended claims to refer to specific elements. Those skilled in the art should understand that electronic device manufacturers may refer to the same element by different names. Herein, it is not intended to distinguish between elements that have the same function but have different names.

In the following description and claims, terms such as “include”, “comprise”, and “have” are open-ended terms, and thus should be interpreted as “including, but not limited to”.

In addition, relative terms, such as “below” or “bottom” and “above” or “top,” may be used in the embodiments to describe the relative relationship of one element to another element of the drawings. It will be understandable that if the device in the drawings is turned upside down, elements described on the “lower” side will become elements described on the “upper” side.

In some embodiments of the disclosure, terms related to bonding and connection such as “connection”, “interconnection”, etc., unless specifically defined, may indicate the case where two structures are in direct contact, or where two structures are not in direct contact and other structures are disposed in between. Moreover, such terms related to bonding and connection may also cover the case where two structures are both movable or where two structures are both fixed. Furthermore, the term “coupling” includes transfer of energy between two structures by means of direct or indirect electrical connection, or transfer of energy between two separate structures by means of mutual induction.

It should be understood that when an element or film layer is referred to as being “on”, or “connected to” another element or film layer, the element or film layer may be directly on or connected to another element or film layer, or intervening elements or film layers may also be present in between (non-direct circumstances). In contrast, when an element or film layer is referred to as being “directly on” or “directly connected to” another element or film layer, no intervening elements or film layers are present in between.

The term “about”, “equal to”, “equivalent” or “same”, “substantially”, or “essentially” is typically interpreted so that a value is within 20% of a given value or range, or within 10%, 5%, 3%, 2%, 1%, or 0.5% of a given value or range.

In this disclosure, optical microscopy (OM), scanning electron microscope (SEM), thin film thickness profilometer (α-step), ellipsometer, or other suitable methods may be used to measure the area, width, thickness or height of various components, or the distance or pitch between components. Specifically, according to some embodiments, a scanning electron microscope may be used to obtain cross-sectional structure images including the components to be measured, and to measure the area, width, thickness or height of each component, or the distance or pitch between components.

In this disclosure, the definition of roughness determination can be observed by SEM. On an uneven surface, the peak-to-valley distance difference of surface undulations can be seen to be between 0.15 micrometers (μm) and 1 μm. Roughness determination measurements may include using SEM, Transmission electron microscope (TEM), etc., to observe the surface undulation conditions under the same appropriate magnification, and comparing the undulation conditions by taking a sample of unit length (e.g., 10 μm) to determine its roughness range. Here, “appropriate magnification” means that at least one surface can see at least 10 undulation peaks in the field of view at this magnification for the roughness (Rz) or average roughness (Ra).

As used herein, the term(s) “film” and/or “layer” may refer to any continuous or discontinuous structure and material (e.g., materials deposited by the methods disclosed herein). For example, films and/or layers may include two-dimensional materials, three-dimensional materials, nanoparticles, or even partial or complete molecular layers, or partial or complete atomic layers, or atomic and/or molecular clusters. The films or layers may include materials or layers having pinholes and may be at least partially continuous.

Although the terms first, second, third, and so on may be used to describe diverse constituent elements, such constituent elements are not limited by the terms. The terms are used only to discriminate one constituent element from other constituent elements in the description. In the claims, the terms first, second, third, etc. may be used in accordance with the order of claiming elements instead of using the same terms. Accordingly, a first constituent element in the following description may be a second constituent element in the claims.

Unless otherwise defined, all terms (including technical and scientific terms) used herein have the same meaning as commonly understood by one of ordinary skill in the art. It is understandable that these terms, such as those defined in commonly used dictionaries, should be interpreted to have a meaning consistent with the background or context of the related art and the disclosure, and not interpreted in an idealized or overly formal manner, unless specifically defined herein.

It should be noted that features in several different embodiments below may be replaced, recombined, mixed with each other to achieve other embodiments without departing from the spirit of the disclosure.

An electronic device of the disclosure may include a power module, a semiconductor device, a semiconductor packaging device, a display device, an antenna device, a sensing device, a light-emitting device, or a tiling device, but not limited thereto. The electronic device may include a bendable or flexible electronic device. The electronic device may include an electronic element. The electronic element may include a passive element, an active element, or a combination of the above, such as a capacitor, a resistor, an inductor, a variable capacitor, a filter, a diode, a transistor, a sensor, a microelectromechanical system element (MEMS), a liquid-crystal chip, etc., but not limited thereto. The diode may include a light-emitting diode or a non-light-emitting diode. The diode includes a P-N junction diode, a PIN diode, or a constant current diode. The light-emitting diode may include, for example, an organic light-emitting diode (OLED), a mini LED, a micro LED, a quantum dot LED, fluorescence, phosphor, or other suitable materials, or a combination of the above, but not limited thereto. The sensor may include, for example, a capacitive sensor, an optical sensor, an electromagnetic sensor, a fingerprint sensor (FPS), a touch sensor, an antenna, or a pen sensor, but not limited thereto. In the following, the display device is used as the electronic device to illustrate the content of the disclosure, but the disclosure is not limited thereto. According to an embodiment of the disclosure, the provided manufacturing method of the electronic device may be applied, for example, to a wafer-level package (WLP) or a panel-level package (PLP) process, and the chip-first process or the chip-last (RDL-first) process may be adopted, which is further described in detail below. The electronic device referred to in the disclosure may include a system-on-package (SoC), a system-in-package (SiP), an antenna-in-package (AiP), or a combination of the above, but not limited thereto.

Reference will now be made in detail to exemplary embodiments of the disclosure, examples of which are illustrated in the accompanying drawings. Wherever possible, the same reference numerals are used in the drawings and description to refer to the same or like parts.

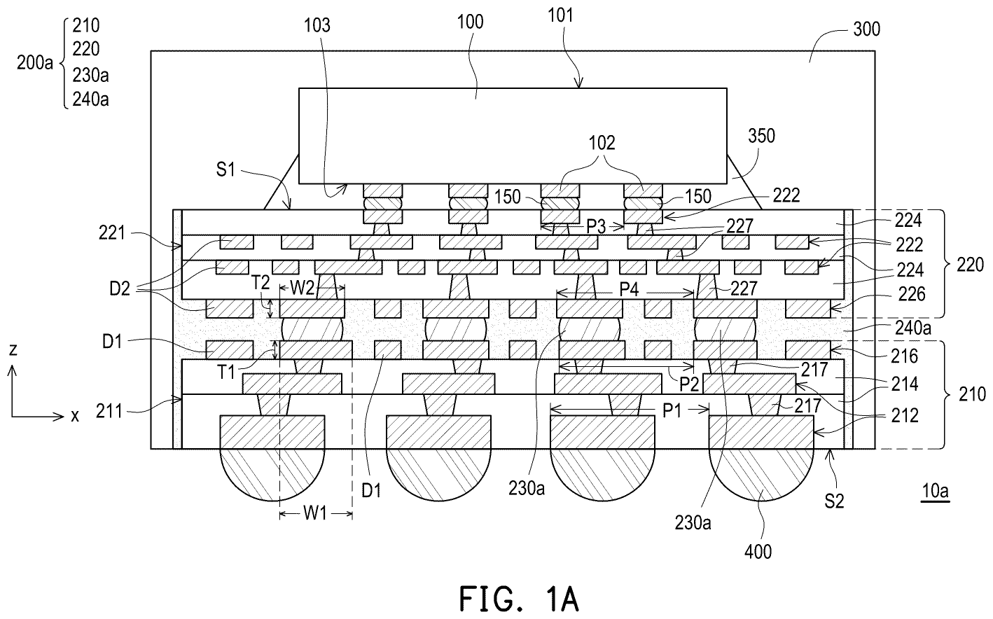

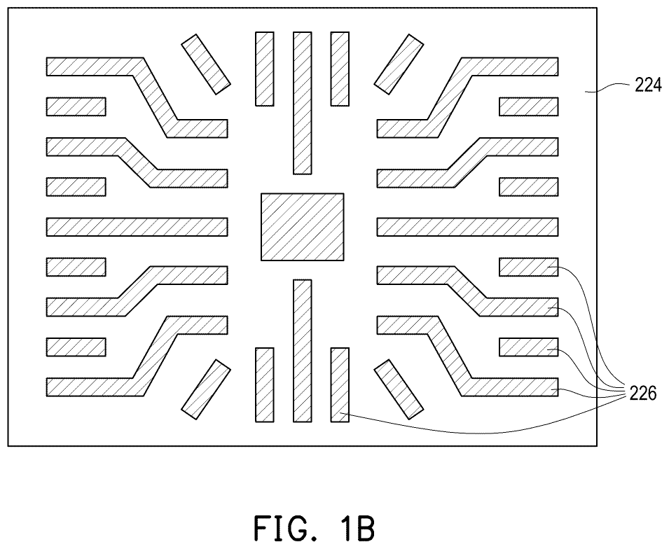

FIG. 1A is a cross-sectional view of an electronic device according to an embodiment of this disclosure. FIG. 1B is a top view of the second circuit structure in FIG. 1A. Referring first to FIG. 1A, the electronic device 10a includes an electronic unit 100 and a circuit structure 200a. The circuit structure 200a is electrically connected to the electronic unit 100, and the circuit structure 200a includes a first circuit structure 210, a second circuit structure 220, bonding pads 230a, and an adjustment layer 240a. The first circuit structure 210 includes at least one first circuit layer (two layers of first circuit layers 212 are schematically shown) and at least one first insulation layer (two layers of first insulation layers 214 are schematically shown) surrounding the first circuit layers 212. The second circuit structure 220 is disposed between the electronic unit 100 and the first circuit structure 210. The second circuit structure 220 includes at least one second circuit layer (three layers of second circuit layers 222 are schematically shown) and at least one second insulation layer (three layers of second insulation layers 224 are schematically shown) surrounding the second circuit layers 222. The bonding pads 230a are disposed between the second circuit structure 220 and the first circuit structure 210. The adjustment layer 240a is disposed between the second circuit structure 220 and the first circuit structure 210 and surrounds the bonding pads 230a. A coefficient of thermal expansion of the adjustment layer 240a is smaller than that of at least one of the first insulation layer 214 of the first circuit structure 210 and the second insulation layer 224 of the second circuit structure 220.

Specifically, the electronic unit 100 of this embodiment may be, for example, passive components, active components, or combinations thereof, such as semiconductor structures, silicon photonic chips, capacitors, resistors, inductors, variable capacitors, filters, diodes, transistors, sensors, micro-electromechanical system (MEMS) components, liquid crystal chips, etc., but is not limited thereto. The electronic unit 100 has a back surface 101 and an active surface 103 opposite to each other, and includes pads 102 disposed on the active surface 103. The electronic unit 100 is, for example, electrically connected to the second circuit structure 220 of the circuit structure 200a through connectors 150. In one embodiment, the connectors 150 may be, for example, eutectic solder, nickel, gold, copper, gallium, alloys, combinations thereof, or other suitable materials, wherein the material of the eutectic solder may be, for example, gold-tin alloy, silver-tin alloy, nickel-gold-tin alloy, or other suitable materials or combinations of the aforementioned materials, but is not limited thereto.

Moreover, in this embodiment, the first circuit structure 210 further includes a first conductive pattern layer 216 and vias 217. The first conductive pattern layer 216 is disposed on the first insulation layer 214 closest to the second circuit structure 220, and the vias 217 electrically connect two adjacent first circuit layers 212 and electrically connect the first circuit layer 212 and the first conductive pattern layer 216. It should be noted that dummy patterns D1 are included in the first conductive pattern layer 216 and/or the first circuit layer 212, and the dummy patterns D1 may not be electrically connected to the vias 217. According to some embodiments, the dummy patterns D1 may adjust the metal ratio in the first circuit structure 210, or may further adjust the warpage degree of the first circuit structure 210, but is not limited thereto. According to some embodiments, the design of the dummy patterns D1 may enhance the heat dissipation capability of the electronic device 10a. Similarly, the second circuit structure 220 further includes a second conductive pattern layer 226 and vias 227. The second conductive pattern layer 226 is disposed on the second insulation layer 224 closest to the first circuit structure 210, and the vias 227 electrically connect two adjacent second circuit layers 222 and electrically connect the second circuit layer 222 and the second conductive pattern layer 226. It should be noted that dummy patterns D2 are included in the second conductive pattern layer 226 and/or the second circuit layer 222, and the dummy patterns D2 may not be electrically connected to the vias 227.

Please refer to FIG. 1A and FIG. 1B simultaneously. The first circuit structure 210 has a first total metal percentage, while the second circuit structure 220 has a second total metal percentage. The ratio of the second total metal percentage to the first total metal percentage may, for example, be greater than or equal to 0.8 and less than or equal to 1.2, meaning that the first total metal percentage and the second total metal percentage are close in proportion, indicating that the weight and stress generated by the first circuit structure 210 and the second circuit structure 220 are similar. It should be noted that the total metal percentage mentioned here refers to the volume ratio of structures using metal materials in the circuit structure, including circuit layers, conductive pattern layers, vias, and dummy patterns. The aforementioned metal material may be copper, for example, but is not limited thereto. In one embodiment, the material of the first insulation layer 214 and the second insulation layer 224 may be, for example, organic resin, such as epoxy resin, polymer, photosensitive polyimide (PSPI), Ajinomoto build-up film (ABF) or polyimide (PI), silicon oxide, silicon nitride, combinations thereof, or other suitable materials, but is not limited thereto.

Please refer to FIG. 1A again. In this embodiment, a first pitch P1 is between adjacent circuits of the first circuit layer 212, while a second pitch P2 is between adjacent conductive patterns of the first conductive pattern layer 216, and the second pitch P2 is smaller than the first pitch P1, i.e., P2<P1. A third pitch P3 is between adjacent circuits of the second circuit layer 222, and a fourth pitch P4 is between adjacent conductive patterns of the second conductive pattern layer 226, and the third pitch P3 is smaller than the fourth pitch P4, i.e., P3<P4. Preferably, the ratio of the fourth pitch P4 to the second pitch P2 may be, for example, greater than or equal to 0.9 and less than or equal to 1.1, i.e., 0.9≤P4/P2≤1.1. The ratio of the third pitch P3 to the first pitch P1 may be, for example, greater than or equal to 0.03 and less than or equal to 0.6, i.e., 0.03≤P3/P1≤0.6. Furthermore, in this embodiment, the conductive patterns of the first conductive pattern layer 216 may have a first width W1, while the conductive patterns of the second conductive pattern layer 226 may have a second width W2, and the first width W1 may be, for example, greater than or equal to the second width W2. The width referred to in this disclosure is, for example, the maximum width measured along the X direction. In this embodiment, the conductive patterns of the first conductive pattern layer 216 may have a first thickness T1, while the conductive patterns of the second conductive pattern layer 226 may have a second thickness T2, and the first thickness T1 may be, for example, greater than or equal to the second thickness T2. The thickness referred to in this disclosure is, for example, the maximum thickness measured along the Z direction. In other words, the line width and line pitch of the first circuit layer 212 of the first circuit structure 210 may be greater than the line width and line pitch of the second circuit layer 222, while the line width and line pitch of the first conductive pattern layer 216 of the first circuit structure 210 may be greater than or equal to the line width and line pitch of the second conductive pattern layer 226 of the second circuit structure 220. Through the above design, the alignment accuracy between circuit structures may be improved, or the risk of signal transmission loss may be reduced, but is not limited thereto.

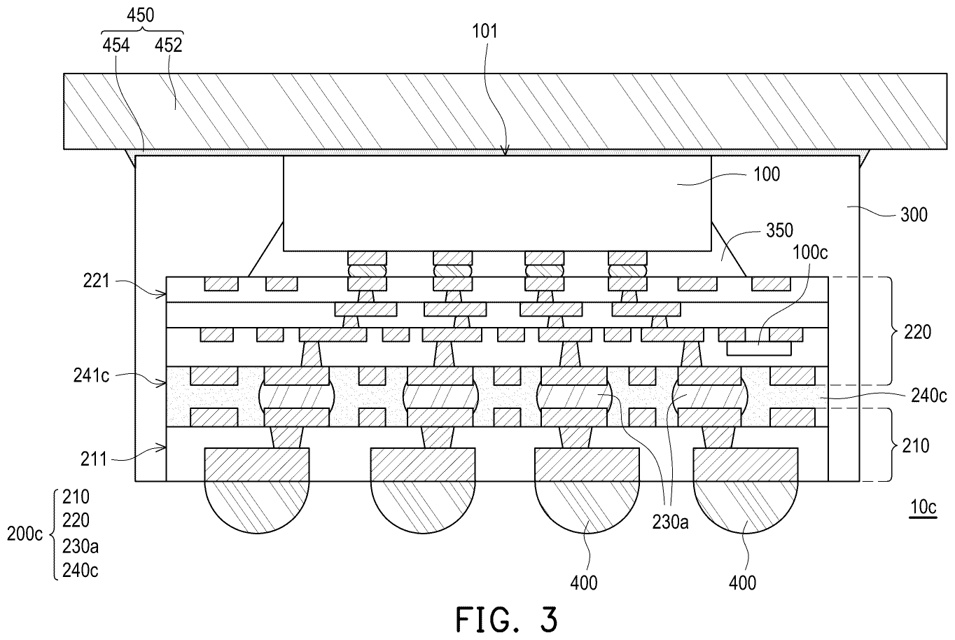

In one embodiment, the circuit structure 200a may be, for example, a redistribution layer (RDL) that reroutes circuits and/or further increases circuit fan-out area, or different electronic units 100 may be electrically connected to each other through the circuit structure 200a. The type of circuit structure 200a is not limited herein. For instance, the circuit structure 200a may be applied in Wafer Level Chip Scale Package (WLCSP), Wafer Level Package (WLP), Panel Level Package (PLP), or other electronic device manufacturing methods, but is not limited thereto. Through the above design, various chips or electronic units may be electrically connected to the circuit structure 200a via bonding pads or other bonding elements. Alternatively, the redistribution layer may be a substrate used as an electrical interface wiring between one connection and another connection. The purpose of the redistribution layer is to extend connections to a wider pitch or redistribute connections to another connection with a different pitch. According to some embodiments, referring to FIG. 3, the circuit structure 200a may include electronic units, which means that electronic units may be embedded or formed within the circuit structure 200a.

Please refer to FIG. 1A again. In this embodiment, the bonding pads 230a are disposed between the first conductive pattern layer 216 of the first circuit structure 210 and the second conductive pattern layer 226 of the second circuit structure 220. In one embodiment, the bonding pad 230a may be, for example, a conductive bump, such as a solder bump or microbump, but is not limited thereto. The second conductive pattern layer 226 is bonded to the first conductive pattern layer 216 through the bonding pads 230a, thereby electrically connecting the second circuit structure 220 to the first circuit structure 210. In other words, this embodiment may form the circuit structure 200a by bonding the second circuit structure 220 to the first circuit structure 210 through solder bonding, microbump bonding, or hybrid bonding methods.

Moreover, in addition to covering the first conductive pattern layer 216, the bonding pads 230a, and the second conductive pattern layer 226, the adjustment layer 240a of this embodiment may also extend to cover the first peripheral surface 211 of the first circuit structure 210 and the second peripheral surface 221 of the second circuit structure 220. In one embodiment, the material of the adjustment layer 240a may be, for example, organic material, inorganic material, or composite material, which may be a single-layer structure, multi-layer structure, or an ultra-thin substrate, but is not limited thereto. In one embodiment, the material of the adjustment layer 240a may be thermosetting material or photocurable material, which may be cured by heat or light, but is not limited thereto.

In particular, the coefficient of thermal expansion (CTE) of the adjustment layer 240a may be smaller than that of at least one of the first insulation layer 214 of the first circuit structure 210 and the second insulation layer 224 of the second circuit structure 220. That is, the CTE of the adjustment layer 240a may be smaller than the CTE of the first insulation layer 214 of the first circuit structure 210, or the CTE of the adjustment layer 240a may be smaller than the CTE of the second insulation layer 224 of the second circuit structure 220, or the CTE of the adjustment layer 240a may be smaller than both the CTE of the first insulation layer 214 of the first circuit structure 210 and the CTE of the second insulation layer 224 of the second circuit structure 220, thereby reducing warpage of the circuit structure 200a during the process. According to some embodiments, the CTE of the adjustment layer 240a may be less than or equal to 10 ppm/° C., less than or equal to 5 ppm/° C., or less than or equal to 3 ppm/° C. According to some embodiments, the CTE of the adjustment layer 240a is less than 0.9 times the CTE of the first insulation layer 214, or the CTE of the adjustment layer 240a is less than 0.8 times the CTE of the first insulation layer 214. Moreover, according to some embodiments, the CTE of the adjustment layer 240a is less than 0.9 times the CTE of the second insulation layer 224, or the CTE of the adjustment layer 240a is less than 0.8 times the CTE of the second insulation layer 224.

On the other hand, the Young's modulus of the adjustment layer 240a may be greater than that of at least one of the first insulation layer 214 and the second insulation layer 224. That is, the Young's modulus of the adjustment layer 240a may be greater than the Young's modulus of the first insulation layer 214, or the Young's modulus of the adjustment layer 240a may be greater than the Young's modulus of the second insulation layer 224, or the Young's modulus of the adjustment layer 240a may be greater than both the Young's modulus of the first insulation layer 214 and the Young's modulus of the second insulation layer 224, thereby reducing warpage of the circuit structure 200a during the process. For example, the adjustment layer 240a may use underfill material with a Young's modulus range between 9.5 GPa to 15 GPa, while the first insulation layer 214 and the second insulation layer 224 may use materials such as photosensitive polyimide (PSPI) or Ajinomoto build-up film (ABF) with a Young's modulus range between 2 GPa to 9 GPa, but not limited thereto. Due to the different material choices for the adjustment layer 240a and the first insulation layer 214 and the second insulation layer 224, the thermal expansion trend of the adjustment layer 240a is also different from the thermal expansion trends of the first insulation layer 214 of the first circuit structure 210 and the second insulation layer 224 of the second circuit structure 220. Here, the thermal expansion trend refers to the upward bending (like a turtle shell) or downward bending (like a bowl) along the Z direction after the material layer thermally expands. By having the thermal expansion trend of the adjustment layer 240a different from the thermal expansion trends of the first insulation layer 214 and the second insulation layer 224, i.e., the warpage directions are opposite, for example, warpage can be reduced, allowing the electronic device 10a to have better structural reliability.

In addition, the electronic device 10a of this embodiment also includes an encapsulation layer 300 surrounding the electronic unit 100 and the circuit structure 200a. In other words, in a cross-sectional view, the encapsulation layer 300 may at least contact one side edge of the electronic unit 100. Here, the encapsulation layer 300 at least covers the back surface 101 of the electronic unit 100 and the adjustment layer 240a, but is not limited thereto. In one embodiment, the material of the encapsulation layer 300 may be, for example, Epoxy Molding Compound (EMC), where the encapsulation layer 300 may be formed by a molding process, but is not limited to this. Moreover, the electronic device 10a of this embodiment also includes an adhesive layer 350 disposed between the electronic unit 100 and the second circuit structure 220, where the adhesive layer 350 at least covers the pads 102 of the electronic unit 100 and the connectors 150. In one embodiment, the adhesive layer 350 may be, for example, an underfill layer that directly contacts the active surface 103 of the electronic unit 100 and the surface S1 of the second circuit structure 220 relatively far from the first circuit structure 210, and fills the spaces between two adjacent connectors 150 and between two adjacent pads 102. In one embodiment, the adhesive layer 350 is used to protect the connectors 150 or ensure the bonding between the electronic unit 100 and the circuit structure 200a. In one embodiment, the material of the adhesive layer 350 may be, for example, resin, epoxy resin, or molding compound, but is not limited thereto. Additionally, the electronic device 10a of this embodiment also includes solder balls 400 disposed on the surface S2 of the first circuit structure 210 relatively far from the second circuit structure 220, where the electronic device 10a may electrically connect to an external circuit through the solder balls 400.

In brief, the adjustment layer 240a of this embodiment is disposed between the second circuit structure 220 and the first circuit structure 210 and surrounds the bonding pads 230a, where the coefficient of thermal expansion of the adjustment layer 240a is smaller than that of at least one of the first insulation layer 214 of the first circuit structure 210 and the second insulation layer 224 of the second circuit structure 220. This may effectively reduce the warping of the substrate, ensure the process accuracy of the pads (i.e., the second circuit layer 222) corresponding to the electronic unit 100 located at the topmost layer, and enable the electronic device 10a of this disclosure to have better structural reliability.

It should be noted that the following embodiments reuse the component labels and some content from the previous embodiments, where the same labels are used to represent the same or similar components, and explanations of identical technical content are omitted. For explanations of the omitted parts, please refer to the previous embodiments. The following embodiments will not repeat these descriptions.

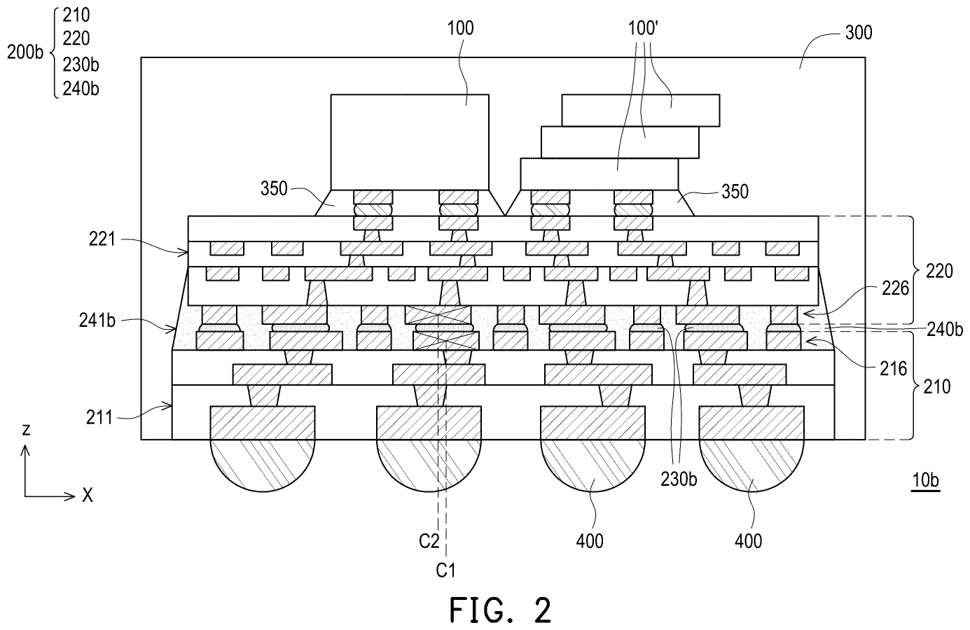

FIG. 2 is a cross-sectional view of another embodiment of an electronic device according to this disclosure. Please refer to FIG. 1A and FIG. 2 simultaneously. The electronic device 10b of this embodiment is similar to the electronic device 10a in FIG. 1A, and the difference between the two is: in this embodiment, the bonding pads 230b of the circuit structure 200b may be, for example, a conductive material layer, whose material may be, for example, a solid solution of the first conductive pattern layer 216 or the second conductive pattern layer 226, or according to some embodiments, may be, for example, Electroless Nickel Immersion Gold, electroless nickel immersion gold (ENIG), electroless nickel palladium immersion gold (ENPIG), tin-gold (SnAu), tin-silver (SnAg), tin-indium (SnIn), but not limited thereto. Moreover, the peripheral surface 241b of the adjustment layer 240b in this embodiment may be flush with the first peripheral surface 211 of the first circuit structure 210 or the second peripheral surface 221 of the second circuit structure 220. According to some embodiments, the first peripheral surface 211 of the first circuit structure 210 and the second peripheral surface 221 of the second circuit structure 220 may be misaligned, or, along direction X, the width of the first circuit structure 210 may be different from the width of the second circuit structure 220. The adjustment layer 240b may not cover the first peripheral surface 211 of the first circuit structure 210 and may cover at least a portion of the second peripheral surface 221 of the second circuit structure 220. Furthermore, in this embodiment, the geometric center C1 of the first conductive pattern layer 216 and the geometric center C2 of the second conductive pattern layer 226 may be misaligned. In other words, the projections of geometric center C1 and geometric center C2 on the same plane may have a distance. Here, the geometric center refers to the intersection point of the diagonals of the entire structural layer, where at least a portion of the second conductive pattern layer 226 may not overlap or may partially overlap with the first conductive pattern layer 216. Additionally, it may include multiple electronic units 100′, where the electronic units 100′ may be stacked along direction Z.

FIG. 3 is a cross-sectional schematic view of an electronic device according to another embodiment of the present disclosure. Please refer to FIG. 1A and FIG. 3 simultaneously. The electronic device 10c of this embodiment is similar to the electronic device 10a in FIG. 1A, with the difference being: in this embodiment, the peripheral surface 241c of the adjustment layer 240c of the circuit structure 200c is flush with the first peripheral surface 211 of the first circuit structure 210 and the second peripheral surface 221 of the second circuit structure 220. That is, the adjustment layer 240c does not cover the first peripheral surface 211 of the first circuit structure 210 and the second peripheral surface 221 of the second circuit structure 220. Furthermore, the electronic device 10c of this embodiment also includes a heat dissipation component 450, disposed on the back surface 101 of the electronic unit 100 opposite to the electronic structure 200a, which may effectively dissipate heat from the electronic unit 100 and may effectively improve the heat dissipation effect of the electronic device 10c. The heat dissipation component 450 may include a thermal adhesive 454 and a heat sink 452, with the thermal adhesive 454 disposed between the electronic unit 100 and the heat sink 452. According to some embodiments, the thermal adhesive 454 may contact at least a portion of the side of the encapsulation layer 300. Additionally, the electronic unit 100c may be embedded in or disposed within the circuit structure, for example, it may be disposed within the second circuit structure 220, and the electronic unit 100c may be electrically connected to the electronic unit 100, but not limited thereto. According to some embodiments, the electronic unit 100c and the electronic unit 100 may be misaligned, but not limited thereto.

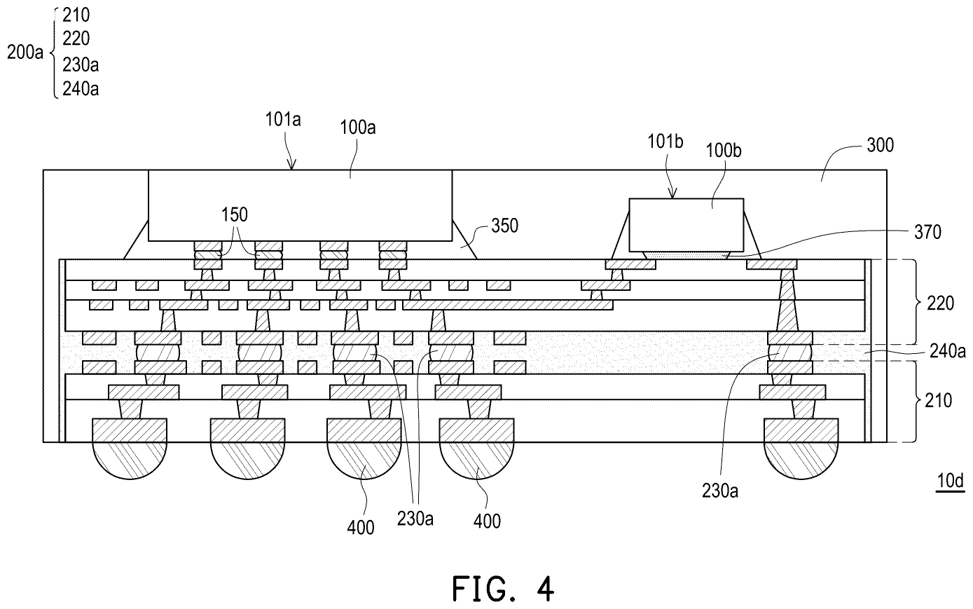

FIG. 4 is a cross-sectional schematic view of an electronic device according to another embodiment of the present disclosure. Please refer to FIG. 1A and FIG. 4 simultaneously. The electronic device 10d of this embodiment is similar to the electronic device 10a in FIG. 1A, with the difference being: in this embodiment, the electronic device 10d includes two electronic units 100a, 100b, where electronic units 100a, 100b are electrically connected to the second circuit structure 220 of the circuit structure 200a respectively. In one embodiment, the electronic unit 100a may be, for example, a substrate integrated circuit or memory, but not limited thereto. In one embodiment, the electronic unit 100a may be electrically connected to the second circuit structure 220 through connectors 150 respectively. In one embodiment, the electronic unit 100b may be, for example, a passive component, where this passive component may be, for example, a surface mount device (SMD), capacitor, inductor, resistor, or other suitable electronic components, but not limited thereto. In other words, the second circuit structure 220 may be electrically connected to the electronic units 100a, 100b through connectors 150 or other bonding elements. Furthermore, in this embodiment, the encapsulation layer 300 exposes the back surface 101a of the electronic unit 100a, but covers the back surface 101b of the electronic unit 100b. That is to say, the back surface 101a of the electronic unit 100a is exposed outside the encapsulation layer 300, which may have better heat dissipation effect, while the encapsulation layer 300 encapsulates the electronic unit 100b to prevent water and oxygen invasion, which may have better reliability.

According to some embodiments, an adhesive layer 370 may be further disposed between the electronic unit 100b and the second circuit structure 220, but not limited thereto.

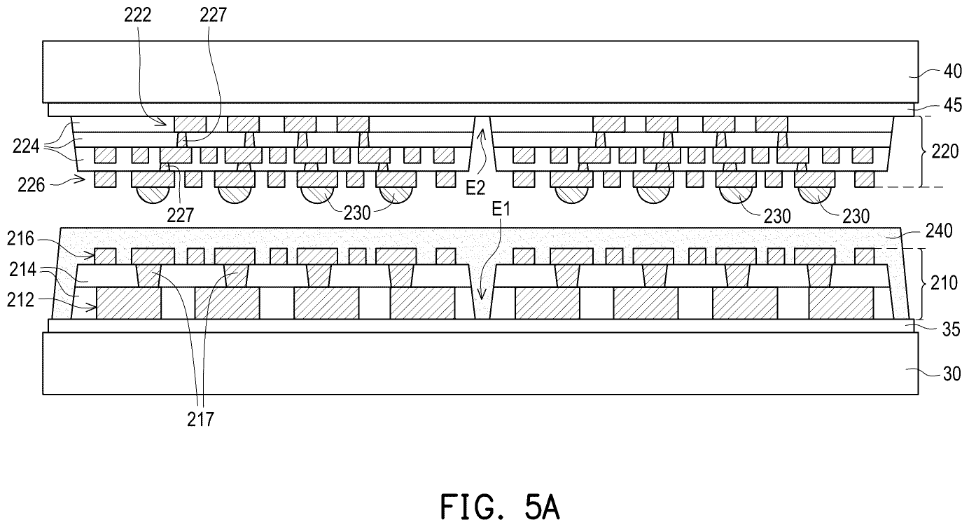

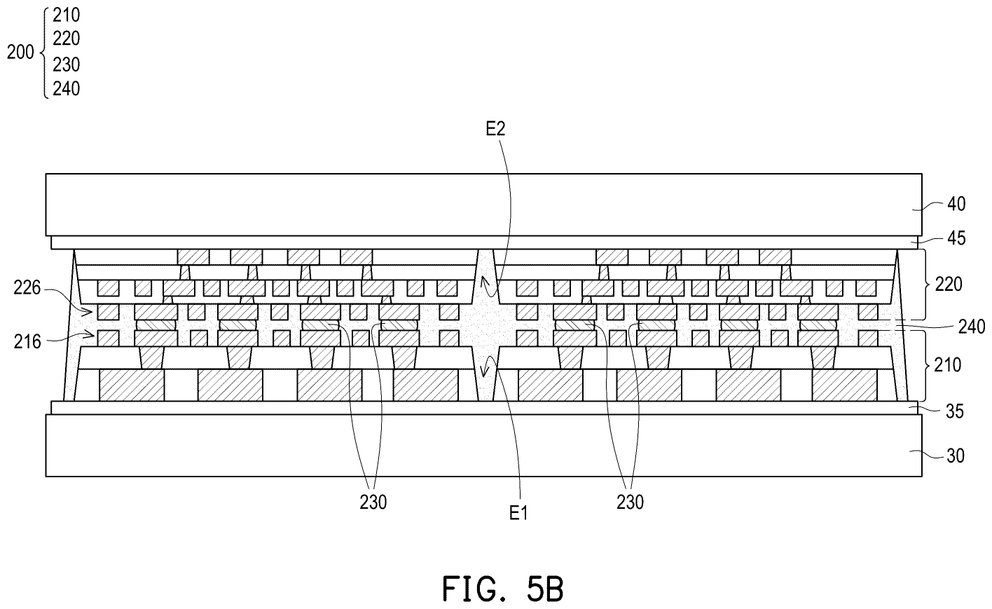

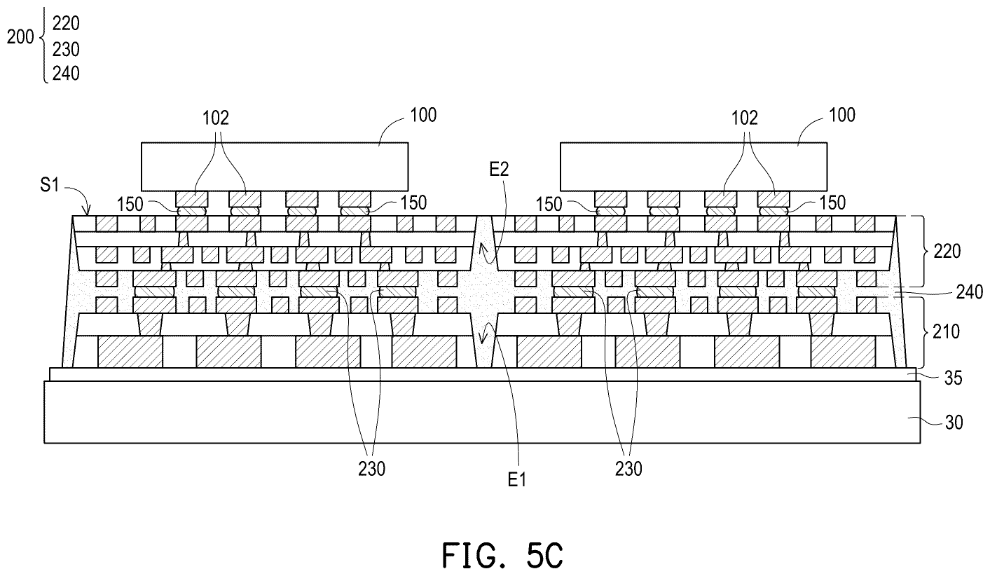

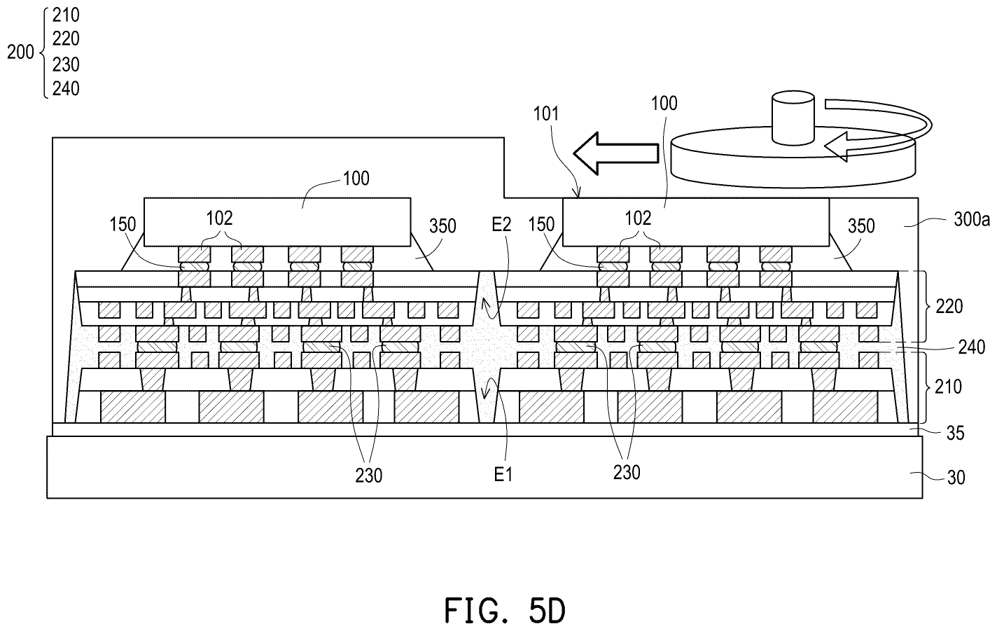

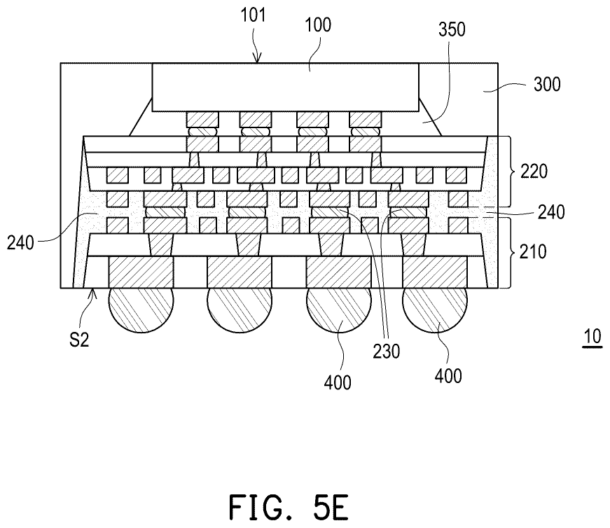

FIG. 5A to FIG. 5E are cross-sectional schematic views of a manufacturing method of an electronic device according to an embodiment of the present disclosure. Please first refer to FIG. 5A. Regarding the manufacturing method of the electronic device of this embodiment, firstly, a first circuit structure 210 and a second circuit structure 220 are provided. The first circuit structure 210 includes a first circuit layer 212, a first insulation layer 214 surrounding the first circuit layer 212, and a first groove E1 passing through the first insulation layer 214. Here, the first circuit structure 210 is formed on a substrate 30, where a release film 35 is present between the substrate 30 and the first circuit structure 210. The second circuit structure 220 includes a second circuit layer 222, a second insulation layer 224 surrounding the second circuit layer 222, and a second groove E2 passing through the second insulation layer 224. The first groove E1 corresponds to the second groove E2. Here, the second circuit structure 220 is formed on a substrate 40, where a release film 45 is present between the substrate 40 and the second circuit structure 220.

Moreover, in this embodiment, the first circuit structure 210 further includes a first conductive pattern layer 216 and vias 217. The first conductive pattern layer 216 is disposed on the first insulation layer 214 closest to the second circuit structure 220, and the vias 217 electrically connect the first circuit layer 212 and the first conductive pattern layer 216. Similarly, the second circuit structure 220 further includes a second conductive pattern layer 226 and vias 227. The second conductive pattern layer 226 is disposed on the second insulation layer 224 closest to the first circuit structure 210, and the vias 227 electrically connect two adjacent second circuit layers 222 and electrically connect the second circuit layer 222 with the second conductive pattern layer 226.

Next, please refer to FIG. 5A again. Bonding pads 230 and an adjustment layer 240 are provided between the first circuit structure 210 and the second circuit structure 220. Here, the bonding pads 230 are formed on the second circuit structure 220, while the adjustment layer 240 is formed on the first circuit structure 210, but this is not limited thereto. The coefficient of thermal expansion of the adjustment layer 240 is smaller than that of at least one of the first insulation layer 214 of the first circuit structure 210 and the second insulation layer 224 of the second circuit structure 220. That is, the coefficient of thermal expansion of the adjustment layer 240 may be smaller than that of the first insulation layer 214 of the first circuit structure 210, or the coefficient of thermal expansion of the adjustment layer 240 may be smaller than that of the second insulation layer 224 of the second circuit structure 220, or the coefficient of thermal expansion of the adjustment layer 240 may be smaller than both the coefficient of thermal expansion of the first insulation layer 214 of the first circuit structure 210 and the second insulation layer 224 of the second circuit structure 220, thereby reducing warpage of the circuit structure 200 (please refer to FIG. 5B) during the process.

Next, please refer to FIG. 5B. For example, through a thermal compression process, the first circuit structure 210 and the second circuit structure 220 are bonded via the bonding pads 230. Here, the bonding pads 230 are located between the first conductive pattern layer 216 and the second conductive pattern layer 226, and the adjustment layer 240 surrounds the bonding pads 230 and fills the first groove E1 and the second groove E2. The adjustment layer 240 is in a liquid state and not yet cured at this stage, and during thermal compression, the liquid or fluid-like adjustment layer 240 may flow to fill the first groove E1 and the second groove E2. In one embodiment, the material of the adjustment layer 240 may be a thermosetting material or a photo-curable material, but is not limited thereto. Subsequently, the adjustment layer 240 may be cured through thermal curing or photo-curing methods. At this point, the first circuit structure 210, the second circuit structure 220, the bonding pads 230, and the adjustment layer 240 may be defined as the circuit structure 200, meaning that this step has completed the fabrication of the circuit structure 200.

Next, please refer to both FIG. 5B and FIG. 5C. The release film 45 and the substrate 40 on it are removed by peeling, thereby exposing the surface S1 of the second circuit structure 220. Immediately following, the electronic unit 100 is disposed on the second circuit structure 220, wherein the electronic unit 100 is, for example, electrically connected to the second circuit structure 220 of the circuit structure 200 through connectors 150.

Next, please refer to FIG. 5D. An adhesive layer 350 is formed between the electronic unit 100 and the second circuit structure 220, wherein the adhesive layer 350 at least encapsulates the pads 102 of the electronic unit 100 and the connectors 150. In one embodiment, the adhesive layer 350 is used to protect the connectors 150 or ensure the bonding between the electronic unit 100 and the circuit structure 200.

Subsequently, please refer to both FIG. 5D and FIG. 5E. An encapsulation material layer 300a is formed on the substrate 30 to encapsulate the electronic unit 100 and the circuit structure 200. Here, the encapsulation material layer 300a completely encapsulates the electronic unit 100 and the adjustment layer 240. Then, optionally, a portion of the encapsulation material layer 300a may be removed by grinding to expose the back surface 101 of the electronic unit 100, thereby forming an encapsulation layer 300 surrounding the electronic unit 100 and the circuit structure 200.

Next, please refer to both FIG. 5D and FIG. 5E again. The release film 35 and the substrate 30 on it are removed by peeling, thereby exposing the surface S2 of the first circuit structure 210. Immediately following, solder balls 400 are formed on the surface S2 of the first circuit structure 210. Finally, a singulation process is performed along the first groove E1 and the second groove E2, cutting the adjustment layer 240 to form the electronic device 10, wherein the electronic unit 100 in the electronic device 10 is electrically connected to the circuit structure 220. At this point, the fabrication of the electronic device 10 is completed.

It should be noted that the singulation cutting process may select the position of the cutting line according to usage requirements. For example, the peripheral surface of the adjustment layer 240 may be cut flush with the peripheral surfaces of the first circuit structure 210 and the second circuit structure 220; or, the peripheral surface of the adjustment layer 240 may be cut flush with the peripheral surface of the encapsulation layer 300; or, the adjustment layer 240 may extend to cover the peripheral surfaces of the first circuit structure 210 and the second circuit structure 220, but is not limited thereto.

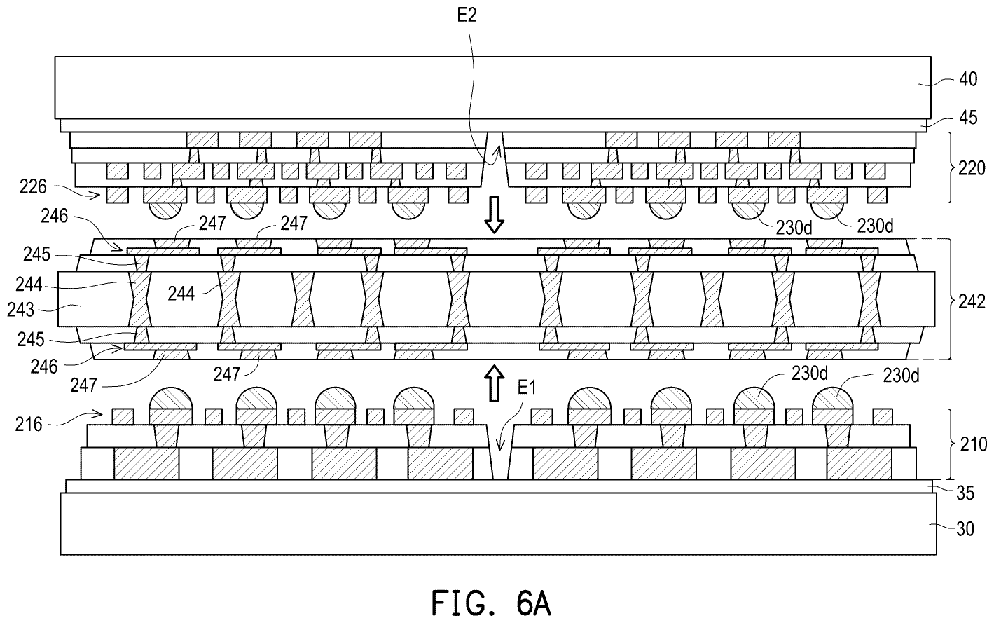

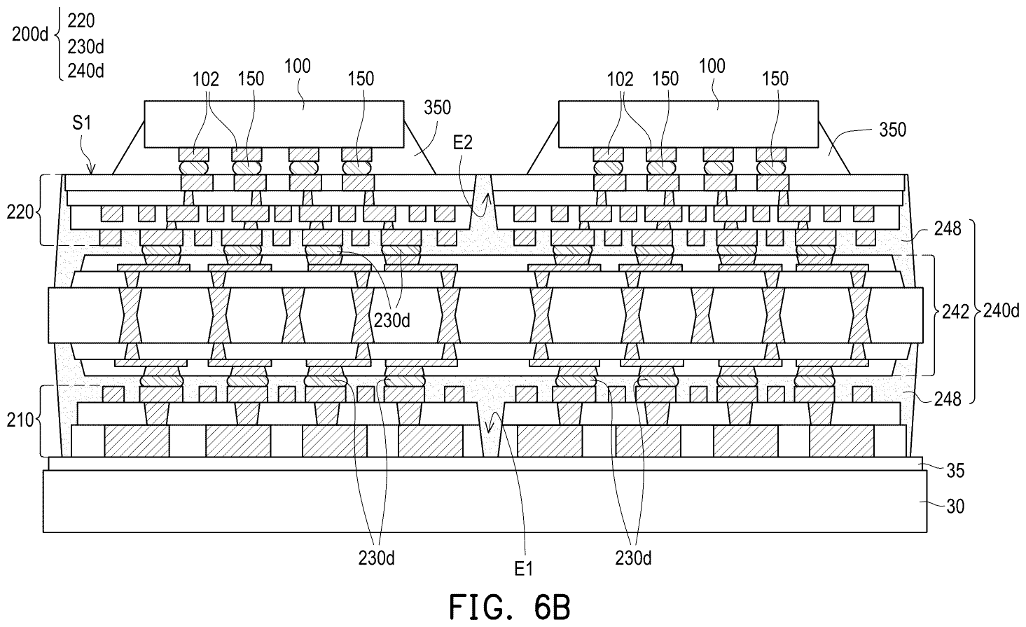

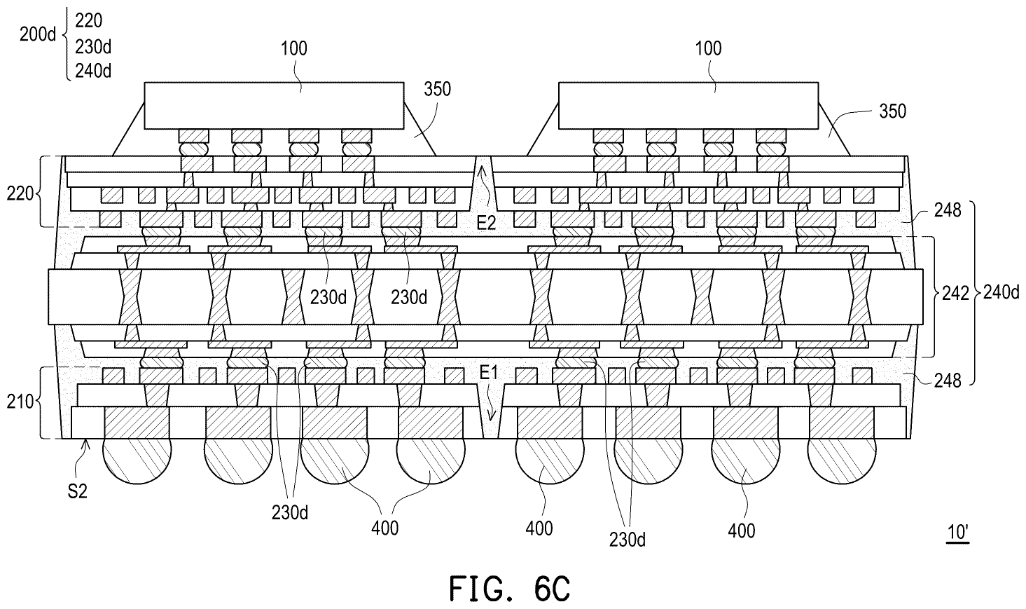

FIG. 6A to FIG. 6C are cross-sectional schematic views of partial steps of a manufacturing method for another embodiment of an electronic device according to the present disclosure. Please refer to both FIG. 5A and FIG. 6B simultaneously. The manufacturing method of the electronic device in this embodiment is similar to the aforementioned manufacturing method of the electronic device. The difference between the two lies in that: in this embodiment, the structure of the adjustment layer 240d is different from the structure of the aforementioned adjustment layer 240.

Specifically, please refer to both FIG. 6A and FIG. 6B. In this embodiment, bonding pads 230d and an adjustment layer 240d are provided between the first circuit structure 210 and the second circuit structure 220. Here, the bonding pads 230d are formed on the first conductive pattern layer 216 of the first circuit structure 210 and on the second conductive pattern layer 226 of the second circuit structure 220. Next, a through-substrate via (TSV) substrate structure 242 is provided between the first conductive pattern layer 216 and the second conductive pattern layer 226. Here, the TSV substrate structure 242 may include a substrate 243, through holes 244 passing through the substrate 243, and build-up structures configured on opposite sides of the substrate 243, which include vias 245, build-up circuit layers 246, and pads 247. The vias 245 are electrically connected to the build-up circuit layers 246 and the through holes 244, while the pads 247 are electrically connected to the build-up circuit layers 246. The substrate 243 may include glass, silicon wafer, ceramic, organic material, a combination of the above, or other suitable materials, but is not limited thereto.

Next, please refer to both FIG. 6A and FIG. 6B again. Using a thermal compression method, the first circuit structure 210 and the second circuit structure 220 are bonded through the bonding pads 230d. At this time, the pads 247 of the TSV substrate structure 242 are bonded with the bonding pads 230d located on the second conductive pattern layer 226 and the first conductive pattern layer 216, so that the second circuit structure 220 is bonded to the first circuit structure 210. Immediately after, adjustment material 248 is filled between the second circuit structure 220 and the TSV substrate structure 242, as well as between the first circuit structure 210 and the TSV substrate structure 242. At this point, the adjustment material 248 surrounds the bonding pads 230d and fills the first groove E1 and the second groove E2. Here, the TSV substrate structure 242 and the adjustment material 248 are defined as the adjustment layer 240d.

Next, please refer to both FIG. 6A and FIG. 6B again. The release film 45 and the substrate 40 on it are removed by peeling, exposing the surface S1 of the second circuit structure 220. Immediately after, the electronic unit 100 is placed on the second circuit structure 220, where the electronic unit 100 is, for example, electrically connected to the second circuit structure 220 of the circuit structure 200 through connectors 150. Immediately after, an adhesive layer 350 may be formed between the electronic unit 100 and the second circuit structure 220, where the adhesive layer 350 at least encapsulates the pads 102 of the electronic unit 100 and the connectors 150. At this point, the first circuit structure 210, the second circuit structure 220, the bonding pads 230d, and the adjustment layer 240d are defined as the circuit structure 200d.

Afterwards, optionally, an encapsulation layer may be formed to encapsulate the electronic unit 100 and the circuit structure 200. Next, please refer to both FIG. 6B and FIG. 6C simultaneously. The release film 35 and the substrate 30 on it are removed by peeling, exposing the surface S2 of the first circuit structure 210. Immediately after, solder balls 400 are formed on the surface S2 of the first circuit structure 210, completing the fabrication of the electronic device 10′.

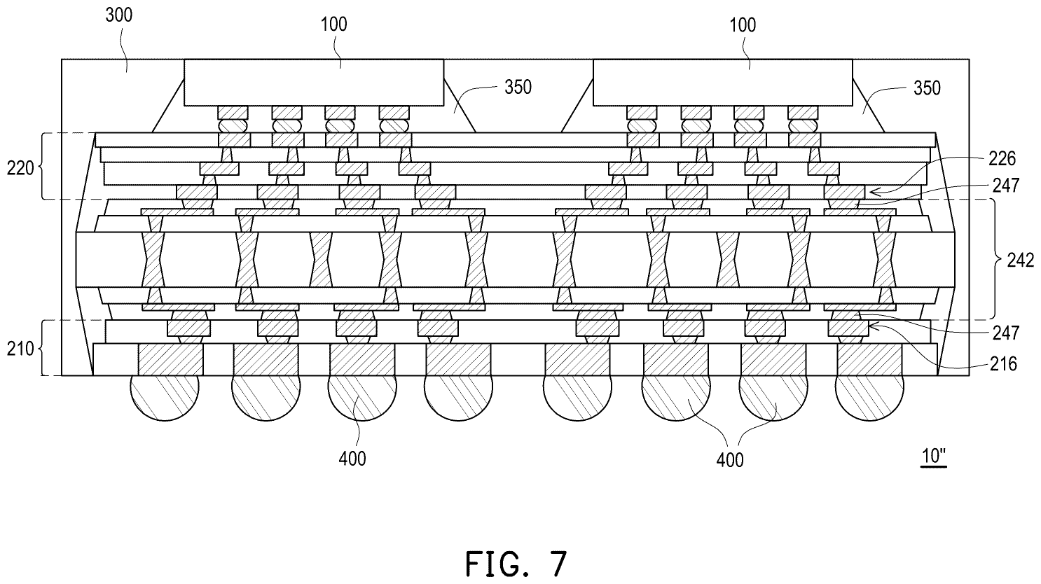

FIG. 7 is a cross-sectional schematic diagram of partial steps in a manufacturing method of an electronic device according to another embodiment of the present disclosure. Please refer to both FIG. 6C and FIG. 7 simultaneously. The manufacturing method of the electronic device in this embodiment is similar to the aforementioned manufacturing method of the electronic device, with the difference being: in this embodiment, a hybrid bonding process is used to bond the pads 247 on one side of the TSV substrate structure 242 with the first conductive pattern layer 216 of the first circuit structure 210, and to bond the pads 247 on the other side of the TSV substrate structure 242 with the second conductive pattern layer 226 of the second circuit structure 220, thereby bonding the second circuit structure 220 to the first circuit structure 210. Compared to solder bonding and microbump bonding methods, the hybrid bonding process may have better electrical performance (such as shorter interconnects, lower resistance, lower power consumption, and lower latency, etc.). Furthermore, the encapsulation layer 300 may be provided to surround the TSV substrate structure 242, the first circuit structure 210, the second circuit structure 220, and the electronic component 100, which may enhance the reliability of the electronic device 10″, but is not limited thereto.

In summary, in an embodiment of the present disclosure, the adjustment layer is disposed between the second circuit structure and the first circuit structure and surrounds the bonding pad, wherein the thermal expansion coefficient of the adjustment layer is smaller than the thermal expansion coefficient of at least one of the first insulation layer of the first circuit structure and the second insulation layer of the second circuit structure, thereby effectively reducing the warping of the substrate, ensuring the process accuracy of the bonding pads corresponding to the electronic unit located in the topmost layer, and enabling the electronic device of the present disclosure to have better structural reliability.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. An electronic device, comprising:
an electronic unit; and
a circuit structure, electrically connected to the electronic unit, the circuit structure comprising:
a first circuit structure, comprising at least one first circuit layer and at least one first insulation layer surrounding the at least one first circuit layer;
a second circuit structure, disposed between the electronic unit and the first circuit structure, the second circuit structure comprising at least one second circuit layer and at least one second insulation layer surrounding the at least one second circuit layer;
a bonding pad, disposed between the second circuit structure and the first circuit structure; and
an adjustment layer, disposed between the second circuit structure and the first circuit structure and surrounding the bonding pad;
wherein a coefficient of thermal expansion of the adjustment layer is smaller than a coefficient of thermal expansion of at least one of the at least one first insulation layer of the first circuit structure and the at least one second insulation layer of the second circuit structure.

2. The electronic device as claimed in claim 1, wherein a thermal expansion trend of the adjustment layer is different from a thermal expansion trend of at least one of the at least one first insulation layer of the first circuit structure and the at least one second insulation layer of the second circuit structure.

3. The electronic device as claimed in claim 1, wherein the bonding pad is disposed between a first conductive pattern layer of the first circuit structure and a second conductive pattern layer of the second circuit structure, and a first width of the first conductive pattern layer is greater than or equal to a second width of the second conductive pattern layer.

4. The electronic device as claimed in claim 3, wherein a first thickness of the first conductive pattern layer is greater than or equal to a second thickness of the second conductive pattern layer.

5. The electronic device as claimed in claim 3, wherein a geometric center of the first conductive pattern layer and a geometric center of the second conductive pattern layer are misaligned.

6. The electronic device as claimed in claim 3, wherein at least one of the first conductive pattern layer and the at least one first circuit layer comprises a dummy pattern.

7. The electronic device as claimed in claim 3, wherein at least one of the second conductive pattern layer and the at least one second circuit layer comprises a dummy pattern.

8. The electronic device as claimed in claim 3, wherein a first pitch is between adjacent circuits of the at least one first circuit layer, and a second pitch is between adjacent conductive patterns of the first conductive pattern layer, and the second pitch is smaller than the first pitch.

9. The electronic device as claimed in claim 8, wherein a third pitch is between adjacent circuits of the at least one second circuit layer, and a fourth pitch is between adjacent conductive patterns of the second conductive pattern layer, and the third pitch is smaller than the fourth pitch.

10. The electronic device as claimed in claim 9, wherein a ratio of the fourth pitch to the second pitch is greater than or equal to 0.9 and less than or equal to 1.1.

11. The electronic device as claimed in claim 9, wherein a ratio of the third pitch to the first pitch is greater than or equal to 0.03 and less than or equal to 0.6.

12. The electronic device as claimed in claim 1, further comprising:
an encapsulation layer, surrounding the electronic unit and the circuit structure.

13. The electronic device as claimed in claim 1, further comprising:
a heat dissipation component, disposed on a back surface of the electronic unit relatively away from the electronic structure.

14. The electronic device as claimed in claim 1, wherein the electronic unit is electrically connected to the second circuit structure of the circuit structure through a connector.

15. The electronic device as claimed in claim 14, wherein the connector comprises eutectic solder, nickel, gold, copper, gallium, alloy or a combination thereof.

16. The electronic device as claimed in claim 1, wherein the first circuit structure has a first total metal percentage, and the second circuit structure has a second total metal percentage, wherein a ratio of the second total metal percentage to the first total metal percentage is greater than or equal to 0.8 and less than or equal to 1.2.

17. The electronic device as claimed in claim 1, wherein a material of the at least one first insulation layer and the at least one second insulation layer comprises organic resin, silicon oxide, silicon nitride or a combination thereof.

18. An electronic device, comprising:
an electronic unit; and
a circuit structure, electrically connected to the electronic unit, the circuit structure comprising:
a first circuit structure, comprising at least one first circuit layer and at least one first insulation layer surrounding the at least one first circuit layer;
a second circuit structure, disposed between the electronic unit and the first circuit structure, the second circuit structure comprising at least one second circuit layer and at least one second insulation layer surrounding the at least one second circuit layer;
a bonding pad, disposed between the second circuit structure and the first circuit structure; and
an adjustment layer, disposed between the second circuit structure and the first circuit structure and surrounding the bonding pad;
wherein a thermal expansion trend of the adjustment layer is different from a thermal expansion trend of at least one of the at least one first insulation layer of the first circuit structure and the at least one second insulation layer of the second circuit structure.

19. A manufacturing method of an electronic device, comprising:
providing a first circuit structure and a second circuit structure, the first circuit structure comprising at least one first circuit layer, at least one first insulation layer surrounding the at least one first circuit layer, and at least one first groove penetrating through the at least one first insulation layer, and the second circuit structure comprising at least one second circuit layer, at least one second insulation layer surrounding the at least one second circuit layer, and at least one second groove penetrating through the at least one second insulation layer, wherein the at least one first groove corresponds to the at least one second groove;
providing a bonding pad and an adjustment layer between the first circuit structure and the second circuit structure, wherein a coefficient of thermal expansion of the adjustment layer is smaller than a coefficient of thermal expansion of at least one of the at least one first insulation layer of the first circuit structure and the at least one second insulation layer of the second circuit structure;
bonding the first circuit structure and the second circuit structure through the bonding pad, wherein the adjustment layer surrounds the bonding pad and fills the at least one first groove and the at least one second groove;
disposing at least one electronic unit on the second circuit structure; and
performing a singulation process along the at least one first groove and the at least one second groove to form at least one electronic device, wherein the first circuit structure, the second circuit structure, the bonding pad, and the adjustment layer are defined as a circuit structure, and the at least one electronic unit is electrically connected to the circuit structure.

20. The manufacturing method of the electronic device as claimed in claim 19, further comprising:
forming an encapsulation layer to surround the electronic unit and the circuit structure before performing the singulation process along the at least one first groove and the at least one second groove.
